(19) United States
(12) Patent Application Publication
(10) Pub. No.: US 2023/0376655 A1
(43) Pub. Date: Nov. 23, 2023

(54) Method for Modelling Geomechanical Pumped Storage in Horizontal Fluid-Filled Lenses

(71) Applicant: Quidnet Energy Inc., Houston, TX (US)

(72) Inventors: Andrew P. Bunger, Pittsburgh, PA (US); Howard K. Schmidt, Hockley, TX (US)

(73) Assignee: Quidnet Energy Inc., Houston, TX (US)

(21) Appl. No.: 18/077,033

(22) Filed: Dec. 7, 2022

Related U.S. Application Data
(60) Provisional application No. 63/287,038, filed on Dec. 7, 2021.

(51) Int. Cl. G06F 30/28

(52) U.S. Cl. CPC G06F 30/28

(57) ABSTRACT

A method for modeling geomechanical subsurface pumped energy storage systems. In one embodiment, the method comprises applying a mechanical model developed for storage lens behavior during flowback (production), shut-in, and inflation (storage) stages. The model couples elastic deformation of the lens with Darcy-Weisbach fluid flow spanning the laminar to turbulent regimes, and includes an energy-based inlet boundary condition governing fluid flow rate out of the lens and up to the Earth's surface. The model also introduces pressure-dependent leakoff of fluid to the surrounding rock and the impact of intact rock bridges, which can arise from the lens having multiple petals or lobes, on lens compliance.

### CROSS-REFERENCE TO RELATED APPLICATIONS

This application is a non-provisional application that claims the benefit of U.S. Provisional Application No. 63/287,038 filed on Dec. 7, 2021, the disclosure of which is incorporated by reference herein in its entirety.

### STATEMENT REGARDING FEDERALLY SPONSORED RESEARCH OR DEVELOPMENT

Not applicable.

### BACKGROUND OF THE INVENTION

### Field of the Invention

The present invention is directed to a method for predictive modeling of the flow performance of a formation fracture utilized in geomechanical subsurface pumped energy storage systems.

### Background of the Invention

Cost-effective energy storage and recovery is essential for the deployment of intermittent renewable energy resources, most notably wind and solar. Traditional pumped hydro storage is typically economically advantageous compared to existing battery technologies, but is typically limited in scope due to dependency on terrain with suitable elevation changes. On the other hand, a novel approach of pumped energy storage in the subsurface has demonstrated the potential to leverage the ubiquitous difference between the density of water and the density of rock to store and recover energy from manufactured fluid-filled lenses in the subsurface.

The principle of subsurface pumped energy storage is conceptually straightforward. In an exemplary embodiment, during construction, a well may be drilled, then hydraulic pressure and engineered fluids may be used to create and seal a storage lens in the subsurface. After forming the sealed lens, energy can be stored by using a pump to inject water into the storage lens (charge). To recover the stored energy (discharge), pressurized water in the lens may be flowed back to surface to drive a hydropower turbine. The pressure and flow rate during the time of discharge typically scales with the difference between the rock density and the fluid density as well as the depth of the lens. Hence, the method bears conceptual similarities to above-ground pumped hydrological energy storage. However, instead of relying on positive elevation and the density of water for storing recoverable gravitational potential energy, subsurface pumped energy storage instead relies on subsurface elevation (depth) and the high stresses found in rocks at depth due to their density in order to store recoverable elastic potential energy. Grid load leveling is one example of many commercial applications of this technology, whereby electricity may be drawn from the power grid during periods of excess generation to charge the storage lens, with the stored energy then discharged back to the grid during periods of high electricity demand.

While the concept is relatively straightforward, mechanical models providing methods by which subsurface pumped energy storage systems can be examined, planned, and designed are not known in the art. Such mechanical models may be essential in order to resolve a wide range of design, planning, and data interpretation issues that arise and/or are expected to arise as this technology is developed, tested, and deployed. Examples of these issues may include setting targets on depth, radius, initial volume, and initial width of the lens in order to produce a desired power level over a desired time frame at optimal efficiency. Such models may also provide a basis for methods allowing interpretation of field data in order to characterize rock properties and volume losses during charge and discharge cycles.

Thus motivated, this disclosure sets out to define a basic model for lens behavior including periods of inflation, shut-in, and flowback as a basis for providing methods for modelling geomechanical pumped storage in horizontal fluid-filled lenses. Although vertically oriented lenses are certainly possible and could be of use in the future, the present disclosure is limited in scope to the case of a horizontal lens that can be approximated to have a circular geometry. This disclosure is organized to firstly present the governing equations embodying the mechanical model, after which some general behaviors are explored with a focus on the individual impacts of mechanisms that are involved in the lens compliance and fluid loss from the lens. Finally, some generic cases are presented to illustrate principles of efficient lens design that minimizes both fluid losses and energy dissipation.

### BRIEF SUMMARY OF SOME OF THE PREFERRED EMBODIMENTS

These and other needs in the art are addressed in one embodiment by a mechanical model directed to modelling lens behavior during flowback (production), shut-in, and inflation (storage) stages. The model couples elastic deformation of the lens with Darcy-Weisbach fluid flow spanning the laminar to turbulent regimes. The model includes an energy-based inlet boundary condition governing fluid flow rate out of the lens and up to the Earth's surface, and also introduces pressure-dependent leakoff of fluid to the surrounding rock and the impact of intact rock bridges, which can arise from the lens having multiple petals or lobes, on lens compliance. The model may then be used to illustrate the transition from early-time gradual decline in wellhead pressure and flow rate to eventual pinching of the lens width at the wellbore, leading to rapid decline of pressure and flow rate. The model can demonstrate the feasibility of efficient storage cycles that generate a desired amount of power over a desired time while avoiding pinching. Maximizing efficiency can be shown through the model to have at least two contrasting regimes depending on whether the fluid leakoff rate to the host rock is dependent on the fluid pressure.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other embodiments for carrying out the same purposes of the present invention. It should also be realized by those skilled in the art that such equivalent embodiments do not depart from the spirit and scope of the invention as set forth in the appended claims.

### BRIEF DESCRIPTION OF THE DRAWINGS

For a detailed description of the preferred embodiments of the invention, reference will now be made to the accompanying drawings in which:

FIG. 1 illustrates an embodiment of a geomechanical pumped storage concept;

FIG. 2 illustrates an embodiment of a mechanical model of a geomechanical pumped storage concept;

FIG. 3A illustrates an embodiment of bridge traction versus lens width model showing a sketch of two idealized bridges connecting faces of a lens separated by a width;

FIG. 3B illustrates an embodiment of an example relationship between bridge traction and width;

FIG. 4A illustrates an embodiment of an illustrative model case with no bridges showing pressure evolution;

FIG. 4B illustrates an embodiment of an illustrative model case with no bridges showing evolution of width profile;

FIG. 4C illustrates an embodiment of an illustrative model case with no bridges showing volumetric flow rate evolution;

FIG. 4D illustrates an embodiment of an illustrative model case with no bridges showing pressure distributions plotted at various times;

FIG. 5A illustrates an embodiment of an illustrative model case with bridge connections showing pressure evolution;

FIG. 5B illustrates an embodiment of an illustrative model case with bridge connections showing evolution of width profile;

FIG. 5C illustrates an embodiment of an illustrative model case with bridge connections showing volumetric flow rate;

FIG. 5D illustrates an embodiment of an illustrative model case with bridge connections showing pressure distributions plotted at various times;

FIG. 6A illustrates an embodiment of the role of leakoff for a case with injection, shut-in, flowback, and a final period of shut-in showing no leakoff;

FIG. 6B illustrates an embodiment of the role of leakoff for a case with injection, shut-in, flowback, and a final period of shut-in showing Carter leakoff only;

FIG. 6C illustrates an embodiment of the role of leakoff for a case with injection, shut-in, flowback, and a final period of shut-in showing pressure dependent and carter leakoff;

FIG. 7A illustrates an embodiment of an example case of cycling showing volumetric rate and wellhead pressure versus time;

FIG. 7B illustrates an embodiment of an example case of cycling showing flow in and out of a lens;

FIG. 8 illustrates an embodiment of an example showing power input and output and lens volume;

FIG. 9A illustrates an embodiment of an example model of efficiency as a function of mean width and injection rate during inflation with Carter leakoff only;

FIG. 9B illustrates an embodiment of an example model of efficiency as a function of mean width and injection rate during inflation with pressure-dependent leakoff;

FIG. 10A illustrates an embodiment of a contact model and behavior showing a conceptual model of contact on asperities with non-constant cross-sectional area;

FIG. 10B illustrates an embodiment of a contact model and behavior showing an example of internal traction exerted on lens faces as a function of lens width; and

FIG. 11 illustrates an embodiment of superposition of contact and bridge law into a combined traction-width relationship.

### DETAILED DESCRIPTION OF THE PREFERRED EMBODIMENTS

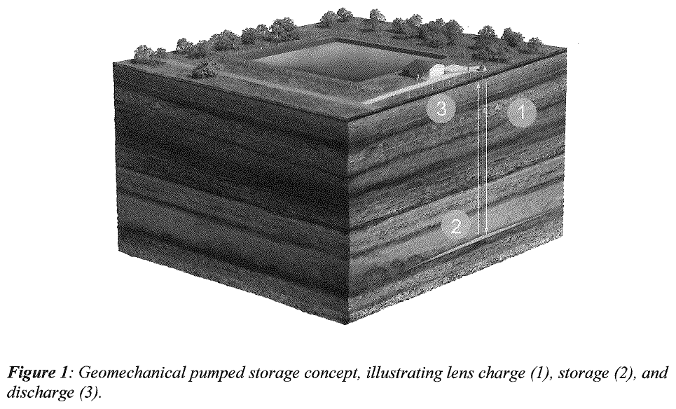

FIG. 1 illustrates an embodiment of a subsurface pumped energy storage system.

During construction, a well may be drilled, after which hydraulic pressure and engineered fluids may be used to create and seal a storage lens in the subsurface. After forming the sealed lens, energy can be stored by using a pump, for example, to inject water into the storage lens to charge the system, shown as step 1, after which the water may be stored in the lens under pressure, shown as step 2. To recover the stored energy by discharging the system, shown as step 3, pressurized water in the lens may be flowed back to surface to drive, for example, a hydropower turbine.

### Lense Model Principles

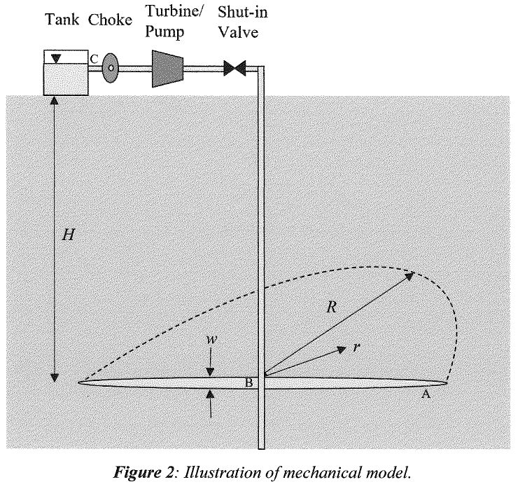

The lens model of the present disclosure seeks to predict wellhead pressure and flow rate as a function of depth, rock properties, and engineering parameters such as volumetric pumping rate during inflation, choke size used to regulate flowback rate, lens radius, and lens volume. The specific model presented herein considers a circular, horizontal planar lens modelled as a fluid-filled crack with initially uniform internal pressure, and embodiment of which is illustrated in FIG. 2. Because the lens could have a radius that is similar to the depth, the model includes the impact of the Earth's surface. The model considers three potential states of the lens, which will be implemented in detail via the boundary conditions imposed at the wellbore. These are: (a) Inflation or charging, where Newtonian, incompressible fluid is injected at a constant rate. It is assumed that a lens of a given radius was already created by a previous injection, and so inflation involves refilling this lens without inducing changes to the lens radius; (b) Flowback or discharging, where Newtonian, incompressible fluid is allowed to flow back to the surface where it turns a turbine and/or passes through a choke that limits its volumetric flow rate according to the choke size and the pressure drop across the choke; and (c) Shut-in, where no fluid is allowed to travel in or out of the lens via its inlet. During this time the pressure in the lens will become spatially uniform, if it had become non-uniform due to a previous injection or flowback phase. At the beginning of time, the lens is taken to be at shut-in with some initial volume, although that volume could be very small if no inflation has yet taken place.

With respect to the first of these assumptions, it may be very limiting in light of the fact that the tip location can, in principle, advance as a result of re-inflation and retreat (at least effectively through closure) during flowback. As may be known in the art, a number of recent contributions have established a theoretical basis pointing to the likelihood that the lens can advance during injection, continue to advance during shut-in, and eventually recede (Peirce and Detoumay 2022a, 2022b, 2022c, and Peirce 2022). However, the moving boundary this brings into the problem can have a significant impact on computational intensity and general complexity of the algorithm, and so it is omitted from the model disclosed herein. In addition to the aforementioned assumptions, the model additionally assumes elastic (recoverable) rock deformation and negligible friction loss through fracture inlet and/or wellbore. The model does, however, consider the potential impact on the lens compliance that may be imparted by intact rock bridges and/or contact on asperities, as will be detailed in the description to follow. The model also considers fluid friction within the lens and fluid loss to the rock both via linear diffusion and via a non-linear fluid loss law that corresponds to pressure-dependent leakoff rate to natural fractures in the host rock.

### Governing Equations

Continuing to refer to FIG. 2, the governing equations begin with an elasticity relationship relating the fluid pressure inside the lens, p_{f}, to the lens width w for a lens of radius R. One approach to solving the radially-symmetric elasticity equation entails superposition of the singular solution for a displacement discontinuity loop in a half-space (Korsunsky 1994, Hills et al. 1996). In this approach, two integral equations can be established (e.g. Zhang et al. 2002, Bunger 2005, Bunger et al. 2013):

$${\int }_{0}^{R} {G}_{n n} ( \frac{r}{R} , \frac{x}{R} ; \frac{R}{H} ) w ( x , t ) d x + {\int }_{0}^{R} {G}_{n s} ( \frac{r}{R} , \frac{x}{R} ; \frac{R}{H} ) {D}_{s} ( x , t ) d x = - \frac{{R}^{2}}{{E}^{′}} ( {p}_{f} + s ( w ) - {σ}_{o} ) \qquad ( 1 )$$

$${\int }_{0}^{R} {G}_{sn} ( \frac{r}{R} , \frac{x}{R} ; \frac{R}{H} ) w ( x , t ) dx + {\int }_{0}^{R} {G}_{s s} ( \frac{r}{R} , \frac{x}{R} ; \frac{R}{H} ) {D}_{s} ( x , t ) dx = 0$$

Here E′ is the plane strain elastic modulus given in terms of Young's modulus E and Poisson's ratio ν as:

$${E}^{′} = \frac{E}{1 - {ν}^{2}}$$

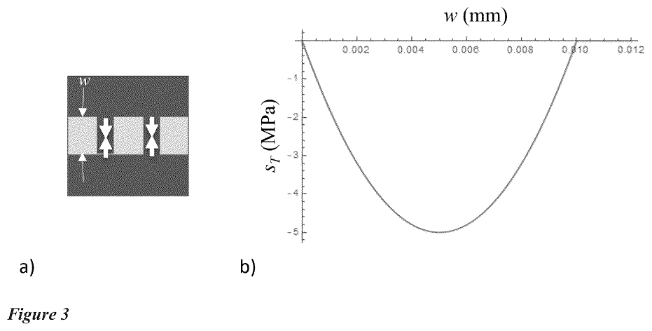

Additionally, Dₛ is the shear component of the displacement discontinuity, which is zero in the case where the lens radius is much smaller than the lens depth (R<<H). Also, the symbolically-intensive elasticity kernels Gag are known in the art (Gordeliy and Detournay 2011) and will not be reproduced here. Finally, the term s is a novel addition to the model. It represents a traction applied to the faces of lens according to a bridge connection law that accounts for elastic deformation of bridge followed by softening due to bridge breakage, with details described by Appendix A and with behavior illustrated by FIGS. 3A and 3B. The expression is given by:

$$s ( w ) = E [ - {η}_{T} {\vert \frac{{w}_{T} - {w}_{max}}{{w}_{T}} \vert}^{{α}_{T}} \frac{w}{{w}_{T}} \hat{H} ( {W}_{T} - {w}_{max} ) ] \qquad ( 2 )$$

where w_{T} is the width at which the bridges break, and wₘₐₓ is the largest width experienced by each location along the lens throughout its inflation history. The Heaviside function Ĥ(⋅) is used to impose zero bridge traction once the breaking width w_{T} is exceeded at a given location at some time in the lens history. Additionally, α_{T} is an exponent describing the shape of the bridge softening curve. Finally, η_{T} is the proportion of the lens surface area that connects to a bridge. Note that there are also expected to be asperity contacts. However, as discussed in Appendix A, except at the smallest apertures it suffices to consider bridge connections only.

The fluid flow part of the model begins with the continuity equation for an incompressible fluid

$$\frac{\partial w}{\partial t} + \frac{1}{r} \frac{\partial }{\partial r} ( r q ) + 2 {v}_{ℓ , mf} = 0 , q = 〈 v 〉 w \qquad ( 3 )$$

where [symbol] ν [symbol] is the mean velocity of the fluid across a cross-section of the lens. The leakoff velocity to the surrounding rock is expressed by [symbol] and has a part that follows the classical Carter law and a part that considers pressure dependent fluid loss to compliant natural fractures, hence

[symbol]

= [symbol] + [symbol] (4)

where the Carter part is (Howard and Fast 1957)

$${v}_{ℓ , m} = \sqrt{\frac{{κ}_{m} {ϕ}_{m} {c}_{r}}{π μ}} \frac{{σ}_{o} - {p}_{0}}{\sqrt{t + {t}_{c}}} \qquad ( 5 )$$

Here κₘ is the permeability of the rock, ϕₘ is the porosity of the rock, cᵣ is the compressibility of the pore fluid, p₀ is the virgin pore pressure, and t_{c} is the time of first contact of the fluid with the lens prior to the beginning of the injection/flowback cycle. In other words, the denominator contains the square root of the contact time, which here is t+t_{c} because t=0 corresponds to a starting point of injection/flowback and at this point the lens radius is fixed. So, by considering the simulation to begin with a fully-extended lens, the fluid first contact with the lens has to be prior to t=0, and hence adding this prior contact time t_{c} gives the total contact time. In classical Carter leakoff, the contact time involves subtracting the time of initial contact, but that is because classical Carter leakoff applies during hydraulic fracture propagation, where at t=0 the hydraulic fracture radius is equal to zero and so the contact time is less than t by an amount equal to the time required to propagate to a certain location.

Continuing with a similar approach to contact time, the pressure dependent part is

$${v}_{ℓ , f} = ( \hat{H} ( {p}_{f} - {σ}_{f} ) \frac{{( {p}_{f} - {σ}_{f} )}^{{α}_{f}}}{{E}^{{α}_{f}}} {ϕ}_{f}^{1 / 2} {L}_{x} ) \sqrt{\frac{{c}_{r}}{π μ}} \frac{{σ}_{o} - {p}_{0}}{\sqrt{t + {t}_{c}}} \qquad ( 6 )$$

This relationship introduces σ_{f}, the closure stress acting on the natural fractures that are accommodating the pressure-dependent leakoff. It also introduces ϕ_{f} and Lₓ, which are the porosity and the nominal length of these natural fractures. Finally, the exponent α_{f} is introduced to relate the rate of change of the aperture to the fluid pressure in the natural fractures, noting that the Heaviside function H(⋅) is used to impose that the permeability of the natural fractures is taken to zero when the pressure drops below closure pressure (leaving only Carter leakoff according to Eq. (5)). Details of the development of the pressure dependent leakoff model are given by Appendix B.

Describing fluid flow also requires a relationship between flux (q) and the pressure gradient, given here by

$$q = - \frac{{w}^{3}}{12 μ {\overline{f}}_{D} ( Re , υ )} \frac{\partial {p}_{f}}{\partial r} , υ = \frac{δ}{2 w} , Re = \frac{2 {ρ}_{f} q}{μ} \qquad ( 7 )$$

Here δ is a roughness height of the surfaces of the lens and ρ_{f} is the fluid density. In this relationship f̅_{D} is a friction factor that depends on Reynold's number (Re). When Re is in a lower range (less than transition value, Reₜᵣₐₙₛ), f̅_{D}→1 and the classical Poiseuille equation for laminar flow is recovered. The specific form of f̅_{D} is provided by an adaptation of Churchill (1977) to hydraulic fracturing by Dontsov and Peirce (2017), and is given by

$${\overline{f}}_{D} ( R e , υ ) = {( 1 + {( \overline{A} + \overline{B} )}^{- 1} )}^{1 / 12} \qquad ( 8 )$$

$$\overline{A} = {( \frac{8.511}{R {e}^{1 / 2}} {f}_{0} ( R e , υ ) )}^{16} , \overline{B} = {( \frac{R {e}_{t r a n s}}{R e} )}^{24}$$

$${f}_{0} ( R e , υ ) = \vert log [ {( \frac{7}{R e} )}^{0.9} + 0.27 υ ] \vert$$

There are a couple of things to note. Firstly, the definition of Reynold's number in Eq. (7) is chosen to match the definition used by Dontsov and Peirce (2017) so that Eq. (8) can be taken directly from their work. There is some discussion in the literature of the proper definition of Reynold's number for hydraulic fractures (or more specifically, of hydraulic radius, see Zia and Lecampion, 2017; Lecampion and Zia, 2019). However, in the present case, there is a subtle but important modification of Eq. (8) that allows the model to sidestep this argument and simply present Reynold's number as in Dontsov and Peirce (2017). Specifically, the transition Reynold's number (Reₜᵣₐₙₛ, Eq. 8) may not be well known for hydraulic fractures, and so it may be preferable to choose it by way of calibration with field data. By leaving this quantity as a parameter to be calibrated, and realizing that the most important contribution of Reynold's number in this formulation comes via B̅, the differences in definitions of Reynold's numbers will be relatively inconsequential as long as a consistent definition is used throughout the calibration process. Besides this issue, the Churchill (1977) formulation has been improved upon in a number of more recent contributions. Notably, Yang and Dou (2010) has been used for hydraulic fracture models by several authors (e.g. Zia and Lecampion, 2017; Zolfaghari and Bunger, 2018; Lecampion and Zia, 2019). However, from the practical perspective undergirding the present work, it is not clear it would substantially improve the model's ability to represent field data, especially in light of the fact that transition Reynold's number and roughness height are both poorly constrained and have to be chosen by way of model calibration.

This completes the description of the field equations. Boundary conditions begin with zero width and flux at the lens tip (after Detournay and Peirce 2014), that is

w(R,t)=0, q(R,t)=0 (9)

The inlet boundary condition requires the fluid flux inside the lens to balance the flow into or out of the well, that is

lim_{r→R}_{_{w}}2πrq=−Q_{BH} (10)

where R_{w} is the wellbore radius and volumetric flow rate Q_{BH} is defined as positive for flowback (lens discharging) and negative for injection (lens charging). Specifically, during lens charging, the volumetric inflow rate to the lens (i.e. injection rate from the pump driving the inflation) is prescribed as Qₜᵣᵢⱼ so that

Q_{BH}=−Qₜᵣᵢⱼ (11)

During flowback, there is a mixed-type boundary condition at the inlet whereby volumetric rate is obtained by writing the classical energy equation of fluid mechanics between a point in the lens and a point just after the choke (FIG. 2), resulting in

$$\frac{{Q}_{B H}^{2}}{{π}^{2}} \frac{8 {ρ}_{f}}{{C}_{d}^{2} {d}_{o}^{4}} = {p}_{f} ( {R}_{w} , t ) - g {ρ}_{f} ( H + {h}_{s} ) \qquad ( 12 )$$

Here C_{d} is the choke shape factor, dₒ is choke diameter, g is gravitational acceleration, and hₛ is the shaft head associated with the work done by the fluid on the turbine. See Appendix C for details.

Finally, under conditions of shut-in the volumetric rate is taken as zero, that is

Q_{BH}=0 (13)

Governing equations are completed by initial conditions for uniformly pressurized lens with a given (user prescribed) initial volume Vᵢ and corresponding internal pressure pᵢₙᵢₜ (which is a part of the solution, not prescribed by the user). That is

2π∫₀^{R}w(r,0)rdr=Vᵢ

q(r,0)=0, p_{f}(r,0)=pᵢₙᵢₜ (14)

### Solution Method

The solution method follows in the spirit of the implicit time marching method described by Gordeliy and Detournay (2011) and using the discretization scheme detailed in Bunger (2005). It entails firstly discretizing the elasticity equation (Eq. (1)) with m constant displacement discontinuity elements and thereby relating the width and pressure according to a displacement discontinuity-type Boundary Element Method (after Crouch and Starfield 1983). The fluid flux equation (Eq. (7)) and continuity equation (Eq. (3)) are then discretized using central differences. Substituting the resulting discretized equations into one another and linearizing the result for a small relative width change at each time step allows for solution by inversion of a matrix. Again, this approach follows Bunger (2005), but with the important difference that the location of the lens tip is fixed and so there is no need for an iteration loop that solves for the lens radius at each time step.

Because of a lack of analytical solutions for benchmarking, the mathematical validation of the model was limited to ensuring a match between the initial solution and the relevant elastic solution for a pressurized crack in cases of a deep and shallow lens for which limiting solutions are given in Bunger and Detournay (2005). Accuracy within ˜1% is obtained using a discretization of ˜100 nodes for R<H. More nodes are needed for larger R/H, similar to what is described in Bunger and Detournay (2005). For example, with R=10H, ˜800 nodes are needed for a similar level of accuracy. While details of the full validation are omitted here for brevity, comparison with some relevant analytical approximations are shown in the following section.

Typical computation times, of course, depend strongly on number of elements, length of each time step, and type of computer. For most practical cases with ˜50-200 nodes and ˜1000-4000 timesteps, a simulation requires around 10-100 seconds to complete on a personal computer with 16 GB RAM and, for these examples, an AMD Ryzen 5 3500U processor. These computation times are to obtain the solution only and do not include time required to write data to file and generate graphical outputs.

### Behavior of the Model

### Deep, Zero Leakoff, Bridge-Free Illustrative Case

During flowback stages, the model predicts the flowback rate with accompanying pressure and lens width distributions. Neglecting the friction losses in the wellbore (as already discussed), the wellhead pressure can be obtained from the predicted pressure at the wellbore wall according to

P_{WH}=p_{f}(R_{w},t)−Hρ_{f}g (15)

Recognize, then, that the pressure in the lens can be decomposed as

p_{f}(R_{w},t)=pₙₑₜ(R_{w},t)+σₒ (16)

where the so-called “net pressure” pₙₑₜ is the transient pressure over and above that which is required to cause first opening of the lens by overcoming the overburden stress so. Furthermore, let

σₒ=f_{g}H (17)

where f_{g} is the closure stress gradient. Bringing these together gives

p_{WH}=pₙₑₜ(R_{w},t)+H(f_{g}−ρ_{f}g) (18)

This shows that the wellhead pressure will be comprised of a constant part that is related to depth. The magnitude of the constant part of the wellhead pressure is also determined by the difference between the closure stress gradient (which comes from the rock density) and the hydrostatic gradient of the fluid column in the wellbore. In comparison to the constant part, the transient net pressure is often small so that

p_{WH}≈H(f_{g}−ρ_{f}g) (19)

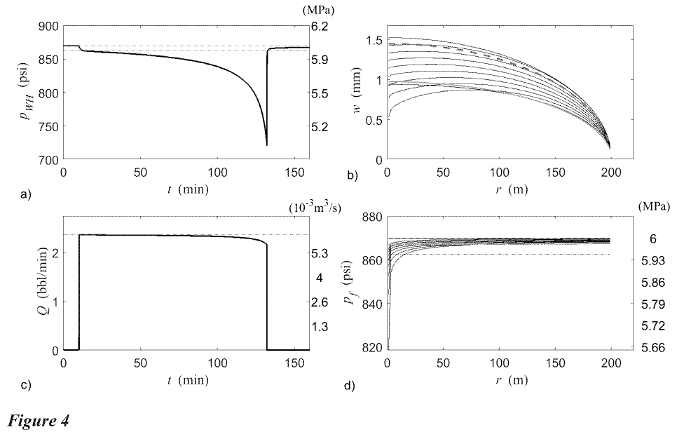

Consider an example case with input parameters given by Table 1. The computed wellhead pressure for this case is indeed observed (FIG. 4A) to be initially slightly larger than the approximation of Eq. (19), with the difference being equal to the net pressure.

It is instructive to observe the net pressure in a bit more detail, considering here an illustrative case in the limit with no rock bridges, large depth, and where prior inflation is assumed to have taken place sufficiently long ago that the internal pressure distribution has become spatially uniform prior to commencement of flowback. In this case with uniform internal pressure and moderately large depth (about 2 times the lens radius), the initial net pressure is readily predicted from the initial volume (Vᵢ) via the classical LEFM solution (Sneddon 1946 as reproduced by Tada et al. 2000)

$${p}_{n e t} ( r , 0 ) = \frac{3 {E}^{′}}{16} \frac{{V}_{i}}{{R}^{3}} \qquad ( 20 )$$

Indeed, FIG. 4A shows the wellhead pressure beginning from a value that is consistent with this initial net pressure. The corresponding initial width profile, shown in FIG. 4B, is similarly consistent with Sneddon's solution, that is

$$w = \frac{8}{π {E}^{′}} {{p}_{n e t} ( {R}^{2} - {r}^{2} )}^{1 / 2} \qquad ( 21 )$$

In actuality, the initial solution for the width slightly exceeds Sneddon's solution. This is because the radius is roughly half of the depth, and so while the impact of the Earth's surface is small, it is not negligible. It can be easily shown (though rather trivially, so omitted here for brevity) that the solution converges to Sneddon as depth is increased. Besides the impact of the surface of the Earth, the initial solution will not match Sneddon's solution if there are bridge connections and/or if the fluid pressure does not achieve spatial uniformity. Also note that in this case, the rebound solution after shut-in (i.e. after 132 minutes in FIG. 4A) returns to Sneddon's solution, just with a smaller volume owing to the fluid that has been allowed to flow back out of the lens (recalling that in the present example leakoff is set at zero). The period of pressure increase commencing at the start of shut-in is therefore associated with pressure inside the lens returning to spatial uniformity after flow ceases.

This example (moderately deep lens, no bridges) is therefore shown to begin (and end) with Sneddon's solution for a uniformly pressurized crack, albeit not quite matching the Sneddon solution due to the small but non-negligible impact of the Earth's surface. Once flowback commences, the volumetric flow rate, Q_{BH}, evolves throughout the flowback period. Substituting the approximation of the wellhead pressure (Eq. (19)) into the inlet boundary condition (Eq. (12)) and solving for Q_{BH} gives an approximation of the flowback rate

$${Q}_{B H} \approx \frac{{π ( {f}_{g} H - g {ρ}_{f} ( H + {h}_{s} ) )}^{1 / 2} {C}_{d} {d}_{o}^{2}}{2 \sqrt{2 {ρ}_{f}}} \qquad ( 22 )$$

This approximation is valid as long as net pressure is small compared to the closure stress σₒ. For the current example, there is no shaft work performed on a turbine and hence hₛ=0. The resulting approximation of Q_{BH} is shown along with the evolving flow rate in FIG. 4C.

During flowback, the pressure is drawn down and with it the flow rate also decreases. The flow rate decrease is not as strong as the decrease of the pressure due to the square root dependence of Q_{BH} on the wellhead pressure. The pressure drawdown is due to a combination of fluid friction developed as fluid flows through the lens and overall reduction in net pressure due to reduction of lens volume. In the current example most of the drawdown is due to fluid friction, evidenced by the fact that the total drawdown substantially exceeds the reduction in pressure between the pre- and post-flowback shut-in periods, which give indication of the magnitude of total drawdown due to reduction in lens volume. After an initial sharp drawdown as flow establishes, a quasi-steady period ensues where both pressure and flowback rate reduce gradually and nearly linearly with time. This continues for a while, until eventually the width becomes small enough that a pinching-type instability occurs. This is an instability in the sense that the pressure drawdown leads to decreased width which further draws down the pressure, and so forth. Once this pinching instability commences, the pressure and flow rate rapidly fall off until the width eventually approaches zero at the inlet. Note that for much of the flowback period in this example, the net pressure is negative near the wellbore even when the lens remains open. This negative net pressure with an open lens is possible owing to the non-locality of the elasticity equations (Eq. (1)). That is, positive net pressure in the outer part of the lens can still hold it open everywhere even when there is a localized region where net pressure is negative (FIG. 4D).

TABLE 1
Input parameter values Input parameter values for illustrative example 1 with no leakoff
and no bridge connections (FIGS. 4A-4D).

| Rock Properties | | | |
|---|---|---|---|
| Young's Modulus, E | 15 GPa (2.2 Mpsi) | Poisson's Ratio, v | 0.33 |
| Closure Stress Gradient, f_{g} | 0.0242 MPa/m | | |
| | (1.07 psi/ft) | | |
| Bridges | | | |
| None | | | |
| Leakoff | | | |
| None | | | |
| Lens Geometry | | | |
| Depth, H | 420 m (1378 ft) | Radius, R | 200 m (656 ft) |
| Initial Volume, Vᵢ | 127 m³ (800 bbl) | Roughness Height, δ | 1 mm |
| Fluid Properties | | | |
| Viscosity | 0.001 Pa s | Density, P_{f} | 1023 kg/m3 |
| Algorithm | | | |
| Number of Elements, m | 100 | Number of Timesteps, nₜ | 3000 |
| Transition Reynolds Number | 800 | | |
| Schedule | Start Time (min) | Description | End Time (min) |
| Stage 1 | 0 | Shut-in | 10 |
| Stage 2 | 10 | Flowback on dₒ = 1 cm choke | 132 |
| | | with shape factor C_{d} = 0.74 | |
| Stage 3 | 132 | Shut-in | 160 |

### Role of Bridges

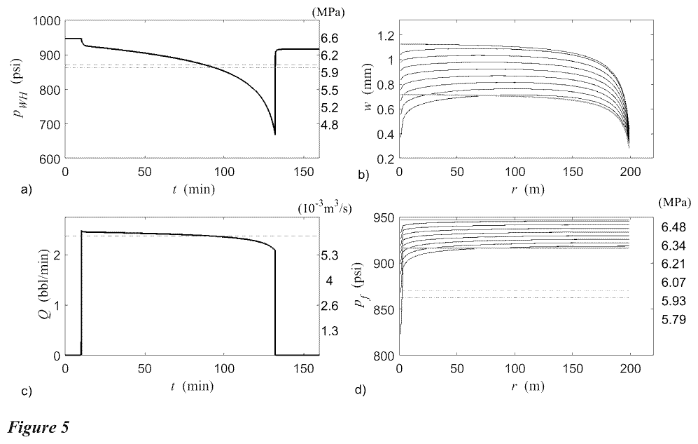

The model allows for existence of bridges that are accounted for in Eq. (2) and detailed in Appendix A. The role of the bridges, in broad terms, is to decrease the lens compliance (i.e. changing the pressure versus volume relationship). The consequences are as follows. Firstly, FIGS. 5A-5D contrast two cases, identical in all ways except in the second case bridges are included with area ratio η_{T}=0.001 (see Table 1). Because the initial volume is the same in both cases, there is not a large difference in the lens width overall. However, the case with bridges has a smaller wellbore width and much more uniform width over the lens compared to the initially ellipsoidal width distribution for the case without bridges. In spite of the lenses having the same volume and radius, the pressure for the case with bridges is significantly larger, indicating smaller elastic compliance. The pressure also falls off significantly more strongly compared to the case with no bridges owing to the larger fluid friction associated with the smaller width near the inlet. Additionally, the time of pinching can occur somewhat earlier for the case with bridges, although in the present examples the pinching times with and without bridges are not significantly dissimilar. From this illustration it is clear that the role of bridges cannot be ignored because, if present, they will impact the leading order behavior of the lens.

TABLE 2
Input parameter values for illustrative example 2 including bridge connections and with
zero leakoff (FIGS. 5A-5D).

| Rock Properties | | | |
|---|---|---|---|
| Young's Modulus, E | 15 GPa (2.2 Mpsi) | Poisson's Ratio, v | 0.33 |
| Closure Stress Gradient, f_{g} | 0.0242 MPa/m | | |
| | (1.07 psi/ft) | | |
| Bridges | | | |
| Connected area ratio, ηᵢ | 2.7e−4 | Breaking width, w_{T} | 6 mm |
| Separation exponent, αₜ | 1.5 | | |
| Leakoff | | | |
| None | | | |
| Lens Geometry | | | |
| Depth, H | 420 m (1378 ft) | Radius, R | 200 m (656 ft) |
| Initial Volume, Vᵢ | 127 m³ (800 bb1) | Roughness Height, δ | 1 mm |
| Fluid Properties | | | |
| Viscosity | 0.001 Pa s | Density, P_{f} | 1023 kg/m3 |
| Algorithm | | | |
| Number of Elements, m | 100 | Number of Timesteps, nₜ | 3000 |
| Transition Reynolds Number | 800 | | |
| Schedule | Start Time (min) | Description | End Time (min) |
| Stage 1 | 0 | Shut-in | 10 |
| Stage 2 | 10 | Flowback on dₒ = 1 cm choke | 132 |
| | | with shape factor C_{d} =0.74 | |
| Stage 3 | 132 | Shut-in | 160 |

### Role of Leakoff

The examples so far have considered the limit with zero leakoff. The contribution of leakoff is generally straightforward; it imposes a fluid loss term where the rate of fluid loss decreases with increasing time since pressurized fluid first contacted the lens. While this mechanism acts throughout the life of the lens (at least while it is inflated with an internal pressure above the surrounding pore pressure), it is most clearly observable as pressure decline during the shut-in stages. In this regard there is a superposition of pressure changes associated with equilibration of pressure during early stages of shut-in along with both Carter-type and pressure dependent leakoff.

To visualize these contributions independently, consider an example with parameter values as in Table 3. Pressure evolution for three cases based on these parameters are shown in Figured 6A-6C. In all three cases, the lens begins with an initial volume of about 32 m³ (200 bbl) and is inflated by injection of 240 m³ (1500 bbl) of fluid at a rate of 0.0265 m³/s (10 bbl/min) for 150 minutes. This inflation is followed by 150 minutes of shut-in (t=150-300 min), 100 minutes of flowback with a 1 cm (0.39 in) choke (t=300-400 min), and a final 100-minute period of shut-in.

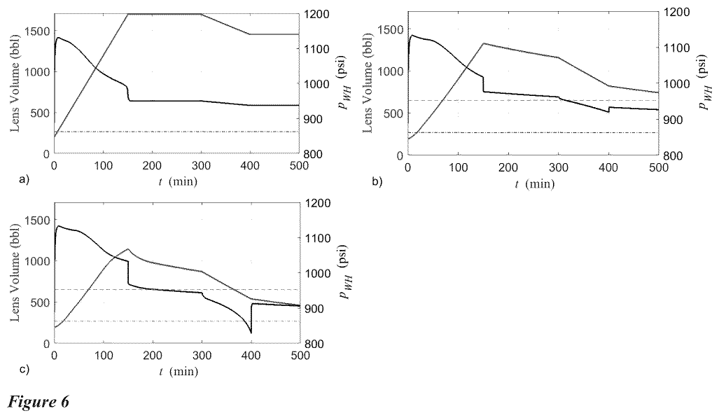

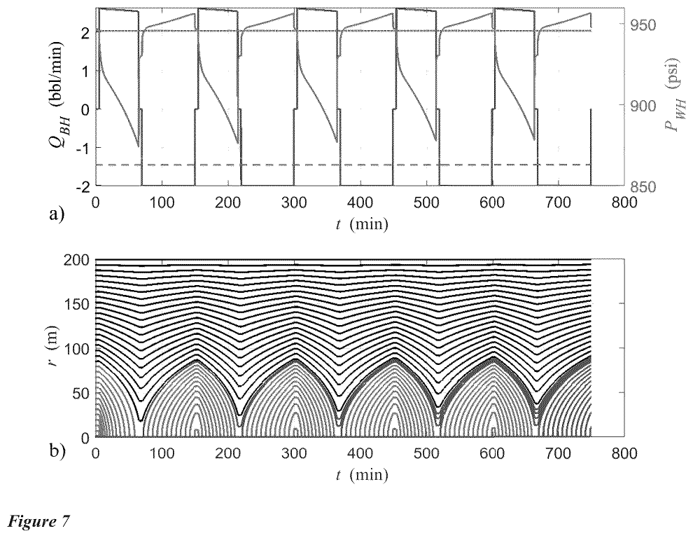

The difference among these cases is in the role of leakoff. In the first case, FIG. 6A, the rock is taken to be impermeable. Here we see the brief transient period of the pressure between injection and shut-in (t=150 min) and between flowback and shut-in (t=400 min), evidencing equilibration of the pressure within the lens from the non-uniform values developed due to fluid friction during both injection and flowback. In this case, however, there is no additional change in the pressure once the internal pressure is equilibrated to a uniform value.

In the second case, Carter leakoff is included (FIG. 6B). The impact of the leakoff is firstly evidenced by the smaller lens volume, which is in spite of injecting exactly the same volume of fluid. Along with this smaller lens volume, there is impact of the leakoff in the form of an additional pressure decline during all stages but most obviously during shut-in stages. Note also that the pressure drawdown during flowback is larger and the steady-state rebound pressure during the second shut-in period is smaller. Both of these are impacts of the lens having smaller volume overall due to the leakoff, which increases fluid friction during flowback and lowers the elastic equilibrium pressure during shut-in.

In the third case (FIG. 6C), both Carter and pressure-dependent leakoff are included. The pressure decline is observed to be considerably larger during the period of initial shut-in where the pressure exceeds the closure stress associated with the natural fractures that accommodate the pressure dependent leakoff. This increased pressure decline is a consequence of more rapid fluid volume loss. The result is much greater pressure drawdown during flowback owing to the smaller volume, hence smaller lens width, hence larger fluid friction.

It is possible, in principle, for the fluid entering the natural fractures to return to the lens during flowback. However, the model does not allow this, assuming instead that all fluid that enters the natural fractures is lost to the formation.

TABLE 3
Input parameter values for illustrative examples showing impact of Carter and pressure
dependent leakoff (FIGS. 6A-6C).

| Rock Properties | | | |
|---|---|---|---|
| Young's Modulus, E | 15 GPa (2.2 Mpsi) | Poisson's Ratio, v | 0.33 |
| Closure Stress Gradient, f_{g} | 0.0242 MPa/m | | |
| | (1.07 psi/ft) | | |
| Bridges | | | |
| Connected area ratio, ηₜ | 2.7e−4 | Breaking width, w_{T} | 6 mm |
| Separation exponent, αₜ | 1.5 | | |
| Leakoff - Case a | | | |
| None | | | |
| Leakoff - Case b | | | |
| Permeability, Kₘ | 1e−5 Darcy | Porosity, ϕₘ | 0.10 |
| Fluid Compressibility, cᵣ | 0.0001 1/MPa | Pore Pressure Gradient, | 0.0113 MPa/m |
| | | fₚ = pₒ/H | (0.5 psi/ft) |
| Contact time, t_{c} | 1 min | | |
| No Pressure Dependent | | | |
| Leakoff | | | |
| Leakoff - Case c | | | |
| Permeability, Kₘ | 1e−5 Darcy | Porosity, ϕₘ | 0.10 |
| Fluid Compressibility, cᵣ | 0.0001 1/MPa | Pore Pressure Gradient, | 0.0113 MPa/m |
| | | fₚ = pₒ/H | (0.5 psi/ft) |
| Contact time, t_{c} | 1 min | NF Closure Gradient, f_{f} | 0.0254 MPa/m |
| | | | (1.135 psi/ft) |
| NF Volume Fraction, ϕ_{f} | 3e−7 | NF Nominal Length, Lₓ | 1 m |
| NF Compliance Exponent, α_{f} | 1 | | |
| Lens Geometry | | | |
| Depth, H | 420 m (1378 ft) | Radius, R | 200 m (656 ft) |
| Initial Volume, Vᵢ | 31.8 m³ (200 bbl) | Roughness Height, δ | 1 mm |
| Fluid Properties | | | |
| Viscosity | 0.001 Pa s | Density, P_{f} | 1023 kg/m3 |
| Algorithm | | | |
| Number of Elements, m | 100 | Number of Timesteps, nₜ | 3000 |
| Transition Reynolds Number | 800 | | |
| Schedule | Start Time (min) | Description | End Time (min) |
| Stage 1 | 0 | Inject at 0.0265 m3/s (10 | 150 |
| | | bbl/min) | |
| Stage 2 | 150 | Shut-in | 300 |
| Stage 3 | 300 | Flowback on dₒ = 1 cm choke | 400 |
| | | with shape factor C_{d} = 0.74 | |
| Stage 4 | 400 | Shut-in | 500 |

### Visualizing Circulation

Additional insights can be gained by visualizing the movement of fluid in and out of the lens during cycling. FIGS. 7A-7B illustrate an example with five cycles of flowback followed by reinflation that restores the lens to its original volume. Each of these flowback and inflation stages is separated by a five-minute shut-in stage. FIG. 7A shows the volumetric injection rate (flowback positive) and wellhead pressure during these cycles. Parameters used to generate this example are given in Table 4.

Then, to visualize the flow, the location of tracer packets of fluid may be tracked. Some of these are distributed uniformly along the lens initially. Additional tracer packets are introduced periodically during inflation. The locations of the packets are tracked explicitly as time progresses, assuming the tracer packets move at the mean velocity of the fluid. Specifically, at each timestep (Δt), the fluid mean velocity (<ν>) is computed based on the model solution for the flux (q) and width (w), recalling <ν>=q/w. Then the change in location of each packet updated by a distance given by <ν>Δt. The resulting virtual streaklines shown in FIG. 7B are color coded as: black indicates tracer packets that start in the lens and never leave the lens; blue indicates tracer packets that flow into the lens during inflation stages but never flow back to the well; and red shows tracer packets that are produced back to the well.

Hence, for this case, the circulating portion of the fluid occupies the inner ˜80 m of the lens. Outside of this region, the fluid is important as it holds the lens open (via the non-locality of the elasticity equations), but it does not circulate in and out of the well. It is also interesting to note the evolution of the blue lines, which is material that is not produced back to the well. Because of the fluid leakoff (about 5 bbl is lost out of the 160 bbl circulated in each cycle), there is always a first portion of fluid injected in each cycle that is not produced back to the well. Instead, it forms a slowly advancing rim of fluid that, in principle, could advance to the tip of the lens over many cycles.

TABLE 4
Parameters used in the cycling example (FIGS. 7A-7B).

| | | | |
|---|---|---|---|
| Rock Properties | | | |
| Young's Modulus, E | 15 GPa (2.2 Mpsi) | Poisson's Ratio, v | 0.33 |
| Closure Stress Gradient, f_{g} | 0.0242 MPa/m | | |
| | (1.07 psi/ft) | | |
| Bridges | | | |
| Connected area ratio, ηₜ | 2.7e−4 | Breaking width, w_{T} | 6 mm |
| Separation exponent, αₜ | 1.5 | | |
| Leakoff - Pressure | | | |
| Dependent Only | | | |
| Permeability, Kₘ | 1e−5 Darcy | Porosity, ϕₘ | 0 |
| Fluid Compressibility, cᵣ | 0.0001 1/MPa | Pore Pressure Gradient, | 0.0113 MPa/m |
| | | fₚ = pₒ/H | (0.5 psi/ft) |
| Contact time, to | 100 min | NF Closure Gradient, f_{f} | 0.0254 MPa/m |
| | | | (1.135 psi/ft) |
| NF Volume Fraction, ϕ_{f} | 3e−7 | NF Nominal Length, Lₓ | 1 m |
| NF Compliance Exponent, α_{f} | 1 | | |
| Lens Geometry | | | |
| Depth, H | 420 m (1378 ft) | Radius, R | 200 m (656 ft) |
| Initial Volume, Vᵢ | 127 m³ (800 bb1) | Roughness Height, δ | 1 mm |
| Fluid Properties | | | |
| Viscosity | 0.001 Pa s | Density, P_{f} | 1023 kg/m3 |
| Algorithm | | | |
| Number of Elements, m | 100 | Number of Timesteps, nₜ | 5000 |
| Transition Reynolds Number | 800 | | |
| Schedule | Start Time (min) | Description | End Time (min) |
| Stage 0 | 0 | Shut-in | 5 |
| Stage 1 | 5 | Flowback on do=1 cm choke | 65 |
| | | with shape factor Ca=0.74 | |
| Stage 2 | 65 | Shut-in | 70 |
| Stage 3 | 70 | Inject at 0.005 m3/s (2 | 150 |
| | | bbl/min) | |
| Repeat 4 times | | | |

### Factors Determining Fluid and Energy Efficiencies

The primary goal of subsurface energy storage is to efficiently store and produce energy at desired rates (i.e. power levels) over desired durations. It remains, then, to examine the efficiency of the proposed flowback-injection cycles. Efficiency can be considered in at least two senses. The first is fluid efficiency, η, which for a given cycle is defined as the ratio of the fluid produced to the fluid that must be injected to restore the lens to the original volume. Hence

$${\int }_{{t}_{0}}^{{t}_{0} + Δ {t}_{F B}} {Q}_{B H} d t = η {\int }_{{t}_{0} + Δ {t}_{FB}}^{{t}_{0} + Δ {t}_{F B} + Δ {t}_{I}} {Q}_{inj} 𝒪 d t \qquad ( 23 )$$

The second useful definition of efficiency is related to the ratio of energy produced to the energy associated with lens inflation (charging and storage). Eventually the energy produced will need to consider details of turbine performance and the ability of the system to keep a given turbine near its most efficient operating point. However, it is instructive at this point to define a round trip efficiency (RTE) in the absence of a turbine, based only on time integration of the hydraulic rate of work associated with flowback and injection. That is

$${\int }_{{t}_{0}}^{{t}_{0} + Δ {t}_{FB}} {p}_{W H} {Q}_{B H} d t = RTE {\int }_{{t}_{0} + Δ {t}_{F B}}^{{t}_{0} + Δ {t}_{F B} + Δ {t}_{I}} {p}_{W H} {Q}_{i η} d t \qquad ( 24 )$$

Both of these definitions (Eqs. (23) and (24)) assume a perfectly restoring injection, that is, returning the lens to the initial volume it had at the commencement of the flowback stage.

For the example previously presented in FIGS. 7A and 7B, the fluid efficiency for each cycle is readily computed by integrating the volumetric flowback and injection rates. By this, it is found that each cycle involves injection of 160 bbl and production of 155 bbl, with loss of about 5 bbl per cycle. Hence, Eq. (23) gives a fluid efficiency of η=0.97. Note that roughly 640 bbl is non-circulating in this example.

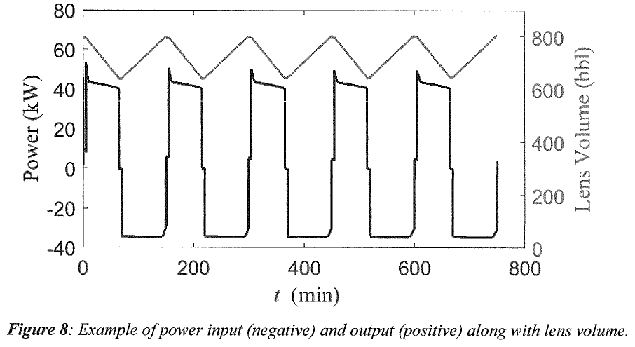

Similarly, the power for this example can be computed as the product of the wellhead pressure and flow rate, as shown in FIG. 8. By integration of these curves, it is found that each flowback stage returns 42.5 kWh, and that restoring to the original volume involves input of 46 kWh. Hence, in this example, according to Eq. (24) the round trip efficiency RTE=0.92.

This example is chosen because it provides a high fluid and energy efficiency for the desired 40 kWh capacity. Lower efficiency designs are possible, and in this regard, the present example is able to provide some additional insights regarding the nature of optimal cycle designs. In each of these cycles the pressure is running to what essentially looks like the beginning of pinching, that is, it starts to sharply decrease (FIG. 7A). One would think that the fluid friction associated with this drop in pressure would be detrimental to the RTE, and indeed it is. From the perspective of limiting fluid friction, it would be better to use a larger initial volume (assuming the same lens radius) in order to have a larger lens width and hence less fluid friction. However, higher volume for a given radius requires larger pressure. In this example, those larger pressures exceed the critical pressure at which pressure-dependent leakoff begins to sharply increase as natural fractures are opened. Hence, an optimal design involves generating as much width as possible but without greatly exceeding the critical pressure for pressure-dependent leakoff.

The other key factor in design optimization is the injection rate Qᵢₙⱼ. Large injection rates lead to smaller efficiencies because of the increase they cause in fluid friction. Also, larger injection rates lead to larger pressures, which can exceed the critical value for pressure-dependent leakoff, also to the detriment of both fluid efficiency and RTE. However, while slower rates reduce fluid friction and pressure-dependent leakoff, they draw out the inflation stage and can allow for more fluid leakoff generally (especially non-pressure-dependent Carter-type leakoff)—and this fluid must be replaced in the next cycle and that replacement requires additional energy. So, for an impermeable rock, the most efficient design will entail injecting as slowly as practical. However, for a permeable rock, optimal efficiency will result from an intermediate value of the injection rate.

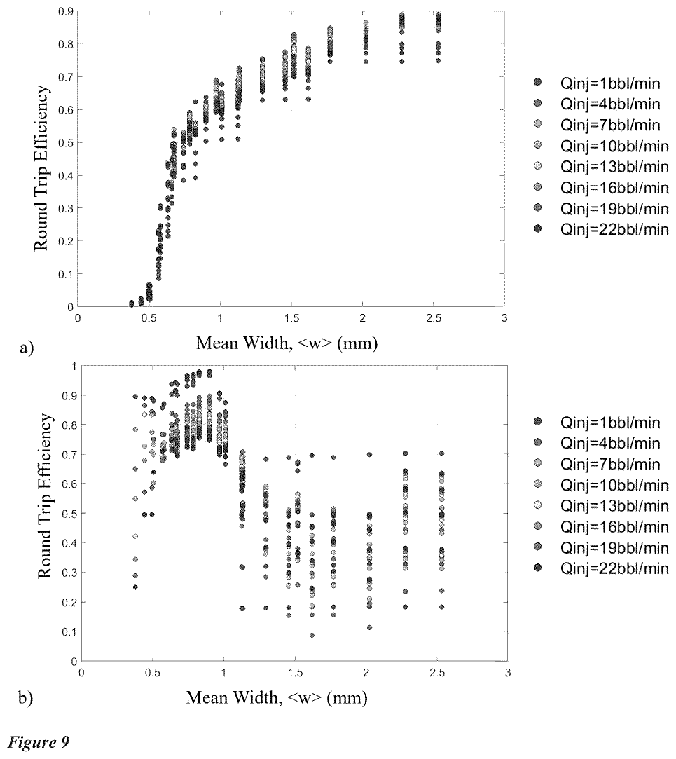

These principles of design in terms of optimal initial lens volume and injection rate are illustrated in FIGS. 9A and 9B. On the one hand, for a case with Carter leakoff only and no pressure-dependent leakoff, the most efficient designs involve the largest possible volume for a given radius (hence the largest width), as shown by FIG. 9A. Furthermore, the maximum RTE for each value of the width is obtained for an intermediate value of injection rate that simultaneously minimizes both fluid friction and pumping time (noting that in this case fluid loss during the cycle simply scales with cycle duration).

On the other hand, when there is pressure dependent leakoff, the approach to optimizing is fundamentally different. FIG. 9B shows such a case (with inputs from Table 4). Here the maximum RTE occurs for values of the width that are large enough to minimize fluid friction and small enough so that the accompanying pressure is only a small amount above the critical value for natural fracture opening. Furthermore, the optimal values of injection rate are near the bottom of the range considered in these simulations, because taking larger values increases the pressure and hence the leakoff rate.

As a final point, it is important to comment briefly on scale up of results from the examples presented herein. These examples are for small, demonstration-scale lenses, remaining in step with development of small-scale demonstration lenses at early stages of technology development. Eventually, commercial-scale lenses are desired that are able to store in the orders of 1-10 MWh of energy. The path to scale up is heavily dependent on the details of a given scenario including target depth, stress gradient, and rock properties. It is also important to realize that simple linear scaling from small to large scale should not be assumed. This is clear from the form of the governing equations, which are non-linear. Notably, increasing initial width has a non-linear impact on reducing the friction related fluid pressure drop via Eq. (7). For example, doubling the width decreases the pressure gradient associated with a given fluid flux by a factor of 8 in the laminar regime (due to the w³ relationship) and a factor of in the fully turbulent regime (due to a N1513 relationship, as described by e.g. Zolfaghari et al. 2018). For this reason, scale up is a nuanced and rich topic for ongoing research and not something that can be approached with simple linear extrapolations from results presented in this disclosure.

### CONCLUSIONS

The model for flowback, shut-in, and reinflation of subsurface energy storage lenses builds on a classical model of hydraulic fracturing in elastic rocks but with a number of important modifications. Most notably, under conditions of flowback the fluid pressure and flow rate at the wellbore are coupled together into a mixed boundary condition that is based on the classical energy equation of fluid mechanics specified for a case with a circular choke and/or a turbine operating at the same elevation as the wellhead. In the current manifestation of the model, there is also a simplifying assumption that the lens radius is fixed, hence the typical issue of tracking a moving boundary in hydraulic fracture growth (or recession) is avoided. Besides these, the model also includes not only Carter-type leakoff (linear diffusion model) but also non-linear pressure dependent leakoff. Finally, the model includes distributed tension springs with certain breaking behavior, representing the impact of intact rock bridges that can have substantial influence of the lens compliance.

The behavior of the model under flowback indicates early-time gradual decline of pressure and even more gradual decline of flow rate. As time goes on, the fluid friction in the lens coupled with elastic deformation of the lens generates a pinching behavior near the wellbore that is associated with rapid decline of the pressure and rate. The timing of this pinching is heavily dependent on the lens radius and volume, which both stem from the dependence of the fluid friction on the lens width. Details of fluid pressure evolution, width profiles, and volume loss are strongly impacted by presence (or not) of rock bridges and/or pressure dependent leakoff.

By computing round trip efficiency, it can be shown that highly efficient cycles are possible. However, such high efficiency requires careful design in terms of initial volume and radius that includes both impacts on lens width (which reduces the fluid friction) and initial fluid pressure (which increases pressure-dependent leakoff). Furthermore, the reinflation rate strongly impacts cycle efficiency, with higher rates leading to higher fluid friction and fluid pressures (and hence higher propensity for pressure-dependent leakoff), while at the same time reducing the fluid loss to non pressure-dependent leakoff. Hence, optimization is shown to be both feasible and nuanced owing to the non-linear dependence of efficiency on governing parameters and the strikingly different considerations that arise in cases with and without pressure dependent leakoff.

Taken together, the illustrative cases using the model disclosed herein show how the development of this model marks a foundational first step in design of subsurface energy storage lenses by providing an essential mechanical basis for predicting lens behavior. Such a model is necessary so that lenses can be designed to generate a desired power over a desired duration, without pinching, and in such a manner that the cycle efficiency is maximized.

### APPENDIX A

### Bridge Model

While a lens could initially be mechanically idealized as a fully open circular crack following the classical Linear Elastic Fracture Mechanics solution of Sneddon (1946), laboratory and field evidence converge on two notable deviations from this idealization. The first is that the we then obtain lens should be expected to have rough surfaces and will therefore close firstly on the largest asperities.

To model asperity contact, consider an asperity contact with a uniform cross sectional area (α). The force this asperity exerts on the inside of the lens, according to linear elasticity, is

$$F = E a \frac{{w}_{C} - w}{{w}_{C}} \hat{H} ( {w}_{C} - w ) \qquad ( 25 )$$

where w_{C} is a neutral displacement at which the asperity exerts no force, w is the width of the lens, and Ĥ(⋅) is the Heaviside step function. For an element (i.e. region) of the lens with area A, the total stress is

$${s}_{C} = \frac{{\sum }_{C ontacts} {F}_{i}}{A} = \frac{\frac{N}{A} A F}{A} \qquad ( 26 )$$

Here N is the number of asperity contacts in the area of the element. By substitution

$${s}_{C} = \frac{N a}{A} E \frac{{w}_{C} - w}{{w}_{C}} \hat{H} ( {w}_{C} - w ) \qquad ( 27 )$$

Introducing the contact area ratio

$$η = \frac{N a}{A} \qquad ( 28 )$$

we the obtain

$${s}_{C} = η E \frac{{w}_{C} - w}{{w}_{C}} \hat{H} ( {w}_{C} - w ) , η = η ( \frac{{w}_{C} - w}{{w}_{C}} ) \qquad ( 29 )$$

The behavior of the area contact ratio is constrained to be

$${{η \vert}_{w = 0} = {η}_{C} , η \vert}_{w = {w}_{C}} = 0 \qquad ( 30 )$$

$$propose : η = {η}_{C} {\vert \frac{{w}_{C} - w}{{w}_{C}} \vert}^{{α}_{C}} \hat{H} ( {w}_{C} - w )$$

Hence compression traction from contact on asperities is given by

$${s}_{c} ( w ) = E [ {η}_{C} {\vert \frac{{w}_{C} - w}{{w}_{C}} \vert}^{1 + {α}_{C}} \hat{H} ( {w}_{C} - w ) ] \qquad ( 31 )$$

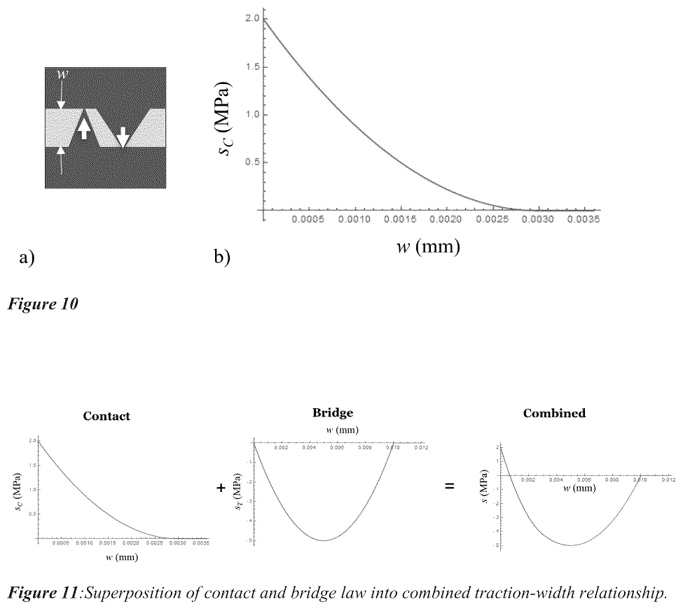

Recall that E is Young's modulus. Also w_{C} is the initial asperity height, η_{C} is the proportion of the lens area that is in contact on asperities, and α_{C} accounts for the change in asperity cross section with closure. For asperities with constant cross section, α_{C}=0. Hence (w_{C}−w)/w_{C} gives axial strain of the asperity, and the Heaviside function Ĥ(⋅) is used to enforce that the contact traction goes to zero when width exceeds the asperity height. Taking E=20 GPa, η_{C}=10⁻⁴, w_{C}=0.003 m, and α_{C}=1, an example of the contact traction as a function of width w is shown in FIG. 10B. The asperity contacts therefore provide a positive traction inside the lens, mechanically equivalent to an additional internal pressure that varies with the width and therefore is prescribed at each node in the discretized lens.

The second deviation from an idealized open lens is that both laboratory and field observations suggest remnant rock bridges are common and are therefore anticipated to exert a non-negligible impact on the pressure-width relationship for a lens. These will be modeled as tension springs. Derivation of a traction-width law for these bridges proceeds in the same manner as for the contacts on asperities. So, consider a bridge connection with a uniform cross-sectional area. The force this bridge exerts on the inside of the lens, according to linear elasticity, is

$$F = - E a \frac{w}{{w}_{B}} \qquad ( 32 )$$

where w is the width of the lens and w_{B} is a reference width for which the elongation ratio of the bridge is 1. For an element (i.e. region) of the lens with area A, the total stress is

$${s}_{T} = \frac{{\sum }_{Bridges} {F}_{i}}{A} = \frac{\frac{N}{A} AF}{A} \qquad ( 33 )$$

Here N is the number of bridges within the area of the element. By substitution

$${s}_{T} = - \frac{Na}{A} E \frac{w}{{w}_{B}} \qquad ( 34 )$$

Introducing the bridge area ratio

$$η = \frac{Na}{A} \qquad ( 35 )$$

we then obtain

$${s}_{T} = - η E \frac{w}{{w}_{B}} \qquad ( 36 )$$

The behavior of the bridge area ratio is proposed to decrease in accordance with a comparison between the maximum width ever experienced at each location of the lens, wₘₐₓ, and a maximum width at which the bridge will break, w_{T}. Hence

$$η {\vert}_{{w}_{max} = 0} = {η}_{0} , η {\vert}_{{w}_{max} = {w}_{T}} = 0 \qquad ( 37 )$$

$$\text{propose:}$$

$$η = {η}_{0} {\vert \frac{{w}_{T} - {w}_{max}}{{w}_{T}} \vert}^{{a}_{T}} \hat{H} ( {w}_{T} - {w}_{max} )$$

where again Ĥ(⋅) is the Heaviside step function. Additionally η₀ is the area of the lens initially covered by bridges and the exponent α_{T} allows for generalized non-linear softening as the bridges fail. Then let us take

w_{T}=βw_{B} (38)

Meaning that β is the elongation ratio at which the bridge fails. For simplicity, let η_{T}=βη₀, the product of the maximum elongation ratio and the initial area of the lens covered by bridges. Taken together, the bridge model becomes

$${s}_{T} ( w ) = - E {η}_{T} {\vert \frac{{w}_{T} - {w}_{max}}{{w}_{T}} \vert}^{{a}_{T}} \frac{w}{{w}_{T}} \hat{H} ( {w}_{T} - {w}_{max} ) \qquad ( 39 )$$

Hence the behavior is characterized by linear increase in tensile traction as the width increases from zero, followed by softening and eventual loss of bridge traction. Taking E=20 GPa, η_{T}=0.001, w_{T}=0.01 m, and α_{T}=1, an example of the bridge-induced traction as a function of width w is shown in FIG. 4B. Note that the bridge criterion ends up being a specific manifestation of a cohesive zone model (see e.g. the review of Park and Paulino, 2011).

The total traction exerted by the combination of contact on asperities and bridges is comprised of the superposition of both traction-width laws, Eqs. (31) and (39). This superposition is illustrated in FIG. 11. This illustration shows that for practically-relevant cases, the bridge only criterion can be nearly same as the combined criterion except for very small width. Furthermore, there is a modeling challenge with the contact criterion that special consideration is needed in order to avoid spurious initial contact traction prior to initial inflation (i.e. it does not naturally satisfy an initial condition of total initial internal traction equaling σo when the lens is initially closed). Taken together, it is found to be both effective and convenient to use bridge criterion only for the current manifestation of the model. However, this simplification could impact ability to track full pressure drawdown when there is a case with hard pinching behavior that takes the width to zero.

### APPENDIX B

### Pressure Dependent Leakoff Model

Presence of pressure dependent leakoff will manifest itself as rapid loss-related pressure decline when pressure is above a certain threshold and slower decline when pressure is below a certain pressure threshold. One approach is to consider pressure-dependent permeability of the rock matrix, which could be tied to existence of compressible microcracks or pre-existing fractures (e.g. Yarushina et al. 2013, Kanin et al. 2020). However, in the storage lens case, the target formations often have extremely small matrix permeability and so there is motivation to explicitly consider natural fracture-dominated pressure-dependent leakoff. So, as a practical means of capturing pressure dependent leakoff, we begin by assuming that the fluid that enters natural fractures is lost to the formation and that it leaks off according to a 1D diffusion law with the transient part of the pressure in the lens is negligible compared to the constant part of the pressure (i.e. pressure in the lens is comprised of a relatively large constant pressure plus a relatively small transient pressure). These are the classical assumptions of Carter (Howard and Fast 1957). Recognizing that the following approach is not formally correct as it takes Carter's leakoff and forces pressure dependence back in without re-solving the original governing equations, it is nonetheless of potential usefulness to express the fluid loss to natural fractures as

$${v}_{ℓ , f} = \sqrt{\frac{{κ}_{f} {c}_{r} {ϕ}_{f}}{π μ}} \frac{{σ}_{o} - {p}_{o}}{\sqrt{t + {t}_{c}}} \qquad ( 40 )$$

Here κ_{f} and ϕ_{f}, are the natural fracture (NF) permeability and volume fraction, respectively. Then let the permeability be related to the NF hydraulic aperture, w_{f}, according to

κ_{f}=w_{f}² (41)

In turn, let the NF aperture depend upon the pressure as

w_{f}=(p_{f}−σ_{f})CₓLₓ (42)

Here Cₓ and Lₓ are the fissure compliance and characteristic length, respectively, and σ_{f} is the closure stress on the dominant NF set(s). This is a linear compliance law, but it is not hard and therefore might be useful to generalize at this point to a non-linear fissure compliance law as

w_{f}=(p_{f}−σ_{f})^{α}^{_{f}}Cₓ^{α}^{_{f}}Lₓ (43)

By keeping the compliance exponent of the same on both the pressure and compliance part of this relationship, it remains dimensionally consistent for any chosen value of α_{f}. Then by substitution the pressure-dependent NF leakoff law is given by

$${v}_{ℓ , f} = {( {p}_{f} - {σ}_{f} )}^{{α}_{f}} {C}_{x}^{{α}_{f}} {L}_{x} \sqrt{\frac{{ϕ}_{f} {c}_{r}}{π μ}} \frac{{σ}_{o} - {p}_{o}}{\sqrt{t + {t}_{c}}} \qquad ( 44 )$$

For most cases the NF length, compliance, and volume fraction will all be poorly constrained. They also appear only as grouped together in Eq. (44). Hence, there are an unnecessary number of free parameters in the current form of Eq. (44). This is practically important because preparing the model for engineering use requires lumping poorly constrained quantities into a few parameters as possible, where the remaining lumped parameters can be selected in order to calibrate the model to field data. So let the compliance be given by 1/E, where E is the Young's modulus of the rock, and let the characteristic length Lₓ be fixed and hard wired to some nominal value (i.e. 1 m). Neither of these assumptions has to be correct, because NF volume fraction will have to be calibrated and will lump together corrections needed. So a simplified model is

$${v}_{ℓ , f} = \frac{{( {p}_{f} - {σ}_{f} )}^{{α}_{f}} {L}_{x}}{{E}^{{α}_{f}}} \sqrt{\frac{{ϕ}_{f} {c}_{r}}{π μ}} \frac{{σ}_{o} - {p}_{o}}{\sqrt{t + {t}_{c}}} \qquad ( 45 )$$

One remaining modification is that the NFs are assumed to close when p_{f}=σ_{f} and their permeability is assumed to go to zero (or at least to match the rock matrix permeability), thus leaving behind only the Carter-type leakoff to the rock matrix. Hence the final form of the pressure-dependent leakoff to the NFs includes a Heaviside step function and is expressed as

$${v}_{ℓ , f} = \hat{H} ( {p}_{f} - {σ}_{f} ) \frac{{( {p}_{f} - {σ}_{f} )}^{{α}_{f}} {L}_{x}}{{E}^{{α}_{f}}} \sqrt{\frac{{ϕ}_{f} {c}_{r}}{π μ}} \frac{{σ}_{o} - {p}_{o}}{\sqrt{t + {t}_{c}}} \qquad ( 46 )$$

### APPENDIX C

### Inlet Boundary Condition

The inlet boundary condition is derived from the classical energy equation of fluid mechanics for fluid flowing from a point just inside the wellbore near the inlet to the lens, point B, up to point C at the discharge of the fluid to surface fluid storage (see FIG. 2). Conservation of energy requires that

h_{B}−Σh_{L}−hₛ=h_{C} (47)

Here h_{B} and h_{C} are the total head at points B and E, respectively, Σh_{L} is the sum of all head losses, and hₛ is the shaft head associated with the work done by the fluid on the turbine. Using the definition of total head (e.g. Hibbeler 2017) and setting the datum at the elevation of the surface equipment (which is assumed to all be at the same elevation), and further assuming no head loss between the fracture inlet and the inside of the wellbore, h_{B} can be expressed as

$${h}_{B} = \frac{{p}_{B}}{{ρ}_{f} g} + \frac{{V}_{B}^{2}}{2 g} + {z}_{B} = \frac{{p}_{f} ( {R}_{w} , t )}{{ρ}_{f} g} + \frac{{V}_{B}^{2}}{2 g} - H \qquad ( 48 )$$

Note that one could include perforation or near wellbore friction losses by moving point B to just inside the lens, but Quidnet's completion technique makes it appropriate to neglect these. Then, using the fact that point C is a free jet and therefore at zero pressure (relative to atmospheric), the total head h_{E} is given by

$${h}_{C} = \frac{{p}_{C}}{{ρ}_{f} g} + \frac{{y}_{C}^{2}}{2 g} + {z}_{C} = 0 + \frac{{V}_{C}^{2}}{2 g} + 0 \qquad ( 49 )$$

With the further assumption that the pipe at C is the same diameter as the pipe at B and that the fluid is incompressible, continuity of fluid flow requires that V_{B}=V_{C}. Additionally, if head losses due to pipe flow are negligible compared to head loss through the choke, it can be taken that

$$\sum {h}_{L} \approx {h}_{choke} = \frac{8}{{π}^{2}} \frac{{Q}_{B H}^{2}}{{gC}_{d}^{2} {d}_{0}^{4}} \qquad ( 50 )$$

Which comes from the classical expression for head loss through an orifice (e.g. Miller 1996), and where Q_{BH} is the volumetric flow rate, C_{d} is the choke shape factor, d₀ is choke diameter, and g is gravitational acceleration.

The shaft head is readily obtained from classical fluid mechanics (e.g. Hibbeler 2017) as

$${h}_{s} = \frac{{P}_{T}}{{eQ}_{B H} {ρ}_{f} g} \qquad ( 51 )$$

where P_{T} is the power generated by the turbine and e is the turbine efficiency.

Bringing all of these equations together leads to the following, which provides the mixed boundary condition relating volumetric flow rate and fluid pressure at the fracture inlet

$$\frac{{p}_{f} ( {R}_{w} , t )}{{ρ}_{f} g} - H - \frac{{P}_{T}}{{eQ}_{BH} {ρ}_{f} g} = \frac{8}{{π}^{2}} \frac{{Q}_{BH}^{2}}{{gC}_{d}^{2} {d}_{0}^{4}} \qquad ( 52 )$$

Although the present invention and its advantages have been described in detail, it should be understood that various changes, substitutions and alterations may be made herein without departing from the spirit and scope of the invention as defined by the appended claims.

What is claimed is:

1. A method of modeling flow performance of a subsurface fracture, comprising:
identifying a formation within which a fracture may be utilized for pumped energy storage and a fluid which may be pumped into or produced from the fracture via a wellbore;
obtaining one or more known characteristics of the formation, fracture, and fluid which impact flow performance of the formation;
assuming one or more unknown characteristics of the formation, fracture, and fluid which impact flow performance of the formation;
inputting the one or more known characteristics of the formation, fracture, and fluid and the one or more assumed characteristics of the formation, fracture, and fluid into a mechanical model of the formation; and
predicting flow performance of the fracture.

2. The method of claim 1, wherein the mechanical model comprises coupling elastic deformation aspects of the lens with Darcy-Weisbach fluid flow spanning the laminar to turbulent regimes.

3. The method of claim 1, wherein one or more of the known or assumed characteristics of the formation comprise a rock elasticity, a rock permeability, a near-wellbore tortuosity, or a near-wellbore perforation loss of the formation, or combinations thereof.

4. The method of claim 1, wherein one or more of the known or assumed characteristics of the fracture comprise a lens radius, or a fracture width of the fracture, or combinations thereof.

5. The method of claim 1, wherein one or more of the known or assumed characteristics of the fluid comprise a compressibility, or a density of the fluid, or combinations thereof.

6. The method of claim 1, further comprising inputting into the mechanical model one or more known or assumed characteristics of one or more surface components acting upon the fluid.

7. The method of claim 6, wherein at least one of the one or more surface components comprises a choke, a shut-in valve, or a turbine, or combinations thereof.

8. The method of claim 1, further comprising calibrating the model against a measured flow performance of a fracture.
